(19) United States
(12) Patent Application Publication
(10) Pub. No.: US 2026/0068494 A1
(43) Pub. Date: Mar. 5, 2026

(54) Transparent Display Apparatus

(71) Applicant: LG Display Co., Ltd., Seoul (KR)

(72) Inventors: Choonghyo Kim, Paju-si (KR); JunHyeok Yang, Paju-si (KR); JiHun Song, Paju-si (KR)

(21) Appl. No.: 19/263,423

(22) Filed: Jul. 8, 2025

(30) Foreign Application Priority Data
Aug. 29, 2024 (KR) 10-2024-0116626

(51) Int. Cl. H10K 59/80; H10K 59/38; H10K 102/00

(52) U.S. Cl. CPC H10K 59/873; H10K 59/38; H10K 59/8792; H10K 2102/351

(57) ABSTRACT

A transparent display apparatus comprises: a substrate having a plurality of pixels each having a transmissive area and a plurality of subpixels; an opposing substrate disposed on the substrate; an encapsulation layer provided to partially cover the opposing substrate; and a spacer disposed between the opposing substrate and the substrate and overlapping the transmissive area, the opposing substrate includes a support area overlapping the spacer, and the encapsulation layer is disconnected in at least a portion of the support area.

### CROSS-REFERENCE TO RELATED APPLICATION

This application claims the benefit of the Republic of Korea Patent Application No. 10-2024-0116626 filed on Aug. 29, 2024, which is hereby incorporated by reference in its entirety.

### BACKGROUND

### Field of Technology

The present disclosure relates to a transparent display apparatus.

### Discussion of the Related Art

With the advancement of the information age, the demand for a display apparatus for displaying an image has increased in various forms. Recently, studies for a transparent display apparatus in which a user may view objects or background positioned at an opposite side by transmitting the display apparatus are actively ongoing.

The transparent display apparatus may include a display area, on which an image is displayed, in a display panel, and the display area may include a transmissive area capable of transmitting external light and a non-transmissive area that does not transmit light. The non-transmissive area may include a plurality of light emission areas having a light-emitting element that emit light.

These transparent display apparatuses mainly adopt a top emission method in which light is emitted upward and can be configured by bonding a lower substrate (or array substrate) on which a plurality of pixels that emit light to display an image are arranged, and an upper substrate (or color filter substrate) on which a plurality of color filters corresponding to each of the plurality of pixel are arranged. However, in transparent display apparatuses, foreign substances may be generated due to the collapse of the cell gap between the lower substrate and upper substrate or sagging of the substrates, and the foreign substances may cause pixel defects. Therefore, it is necessary to maintain the cell gap between the lower substrate and upper substrate.

### SUMMARY

An embodiment of the present disclosure is directed to providing a transparent display apparatus in which a cell gap between a substrate (a lower substrate) and an opposing substrate (an upper substrate) can be maintained.

Further, an embodiment of the present disclosure is directed to providing a transparent display apparatus capable of blocking or at least reducing crack propagation through an encapsulation layer.

Further, an embodiment of the present disclosure is directed to providing a transparent display apparatus capable of preventing or at least reducing moisture penetration into a light-emitting element.

Further, an embodiment of the present disclosure is directed to providing a transparent display apparatus that can be driven with low power compared to the entire lifespan due to improved lifespan of the light-emitting element, thereby reducing power consumption.

Further, an embodiment of the present disclosure is directed to providing a transparent display apparatus in which the cell gap can be increased.

Further, an embodiment of the present disclosure is directed to providing a transparent display apparatus capable of improving the viewing angle.

Further, an embodiment of the present disclosure is directed to providing a transparent display apparatus capable of preventing dark spot defects caused by external force.

The problems to be solved by the examples of the present disclosure are not limited to those mentioned above, and other problems not mentioned will be apparent to one of ordinary skill in the art to which the technical spirits of the present disclosure belong from the following description.

A transparent display apparatus according to an embodiment of the present disclosure comprising: a substrate having a plurality of pixels each having a transmissive area and a plurality of subpixels; an opposing substrate disposed on the substrate; an encapsulation layer provided to partially cover the opposing substrate; and a spacer disposed between the opposing substrate and the substrate and overlapping the transmissive area, the opposing substrate includes a support area overlapping the spacer, and the encapsulation layer is disconnected in at least a portion of the support area.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a transparent display apparatus according to one embodiment of the present disclosure.

FIG. 2 is a schematic enlargement of portion A of FIG. 1, showing a plurality of pixels according to one embodiment of the present disclosure.

FIG. 3 is a schematic cross-sectional view of the line I-I′ shown in FIG. 2 according to one embodiment of the present disclosure.

FIG. 4 is a schematic cross-sectional view of portion B of FIG. 3 according to one embodiment of the present disclosure.

FIG. 5 is a schematic cross-sectional view showing a second example of portion B in FIG. 3 according to one embodiment of the present disclosure.

FIG. 6 is a schematic cross-sectional view showing a third example of portion B in FIG. 3 according to one embodiment of the present disclosure.

FIG. 7 is a schematic cross-sectional view showing a fourth example of portion B in FIG. 3 according to one embodiment of the present disclosure.

FIG. 8 is a schematic cross-sectional view showing a dam of a transparent display apparatus according to one embodiment of the present disclosure.

FIG. 9 is a schematic plan view showing another example of portion A of FIG. 1, relating to a transparent display apparatus according to another embodiment of the present disclosure.

FIG. 10 a schematic cross-sectional view of the line II-II′ shown in FIG. 9 according to one embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings.

The present disclosure may, however, be embodied in different forms and should not be construed as limited to the embodiments set forth herein.

Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely one example, and thus, the present disclosure is not limited to the illustrated details. Like reference numerals refer to like elements throughout.

In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand.

The embodiments of the present disclosure may be carried out independently from each other or may be carried out together in co-dependent relationship.

Hereinafter, the preferred embodiments of the present disclosure will be described in detail with reference to the accompanying drawings.

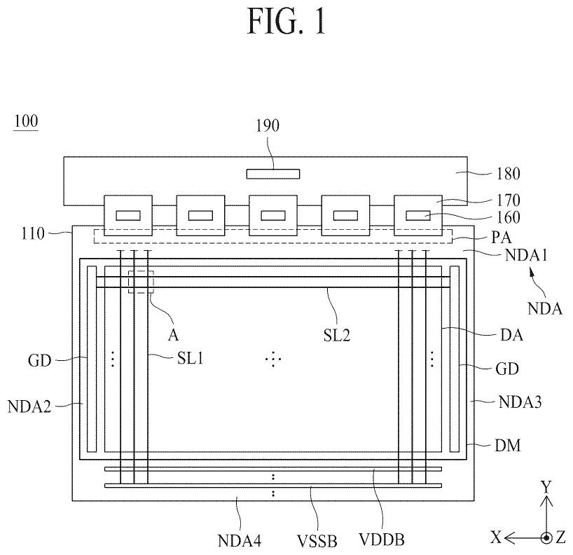

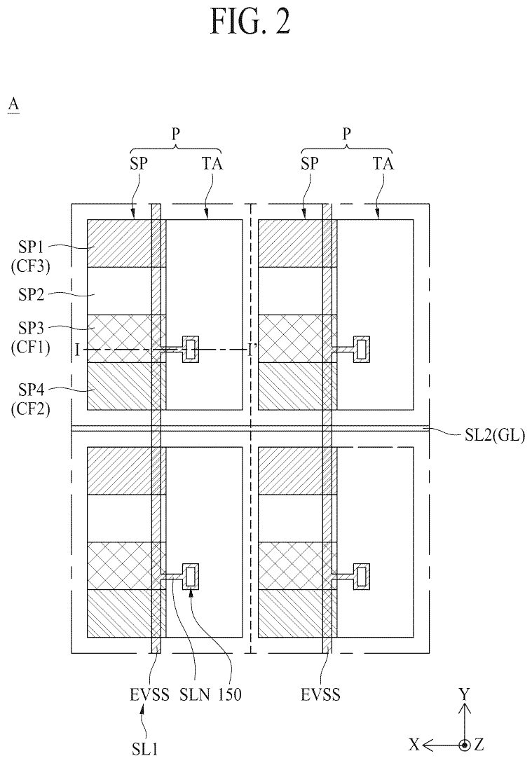

FIG. 1 is a schematic plan view of a transparent display apparatus according to one embodiment of the present disclosure, and FIG. 2 is a schematic enlargement of portion A of FIG. 1, showing a plurality of pixels according to one embodiment of the present disclosure.

Hereinafter, a first direction (Y-axis direction) represents a direction parallel to the common power line EVSS (shown in FIG. 2), a second direction (X-axis direction) represents a direction parallel to the gate line GL (shown in FIG. 2), and a third direction (Z-axis direction) represents a thickness direction of the transparent display apparatus 100.

The following description will be based on that a transparent display apparatus 100 according to one embodiment of the present disclosure is an organic light emitting display apparatus, but is not limited thereto. That is, the transparent display apparatus according to one embodiment of the present disclosure may be implemented as any one of a liquid crystal display apparatus, a field emission display apparatus, a quantum dot lighting emitting diode apparatus, and an electrophoretic display apparatus as well as the organic light emitting display apparatus.

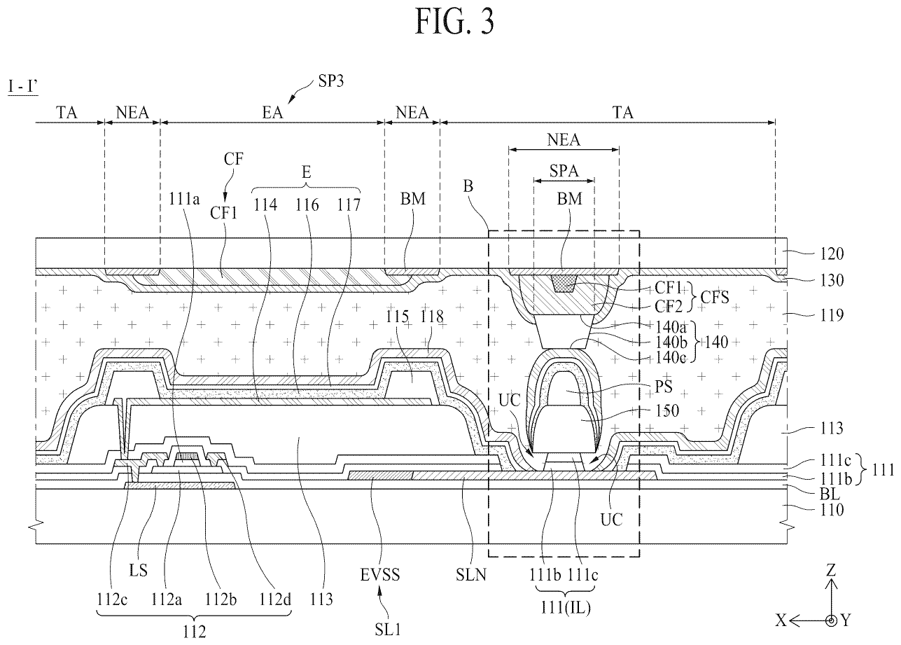

Referring to FIG. 1, the transparent display apparatus 100 according to one embodiment of the present disclosure may include a display panel having a gate driver GD, a source drive integrated circuit (hereinafter, referred to as “IC”) 160, a flexible film 170, a circuit board 180, and a timing controller 190. The display panel may include a substrate 110 and an opposing substrate 120 (shown in FIG. 3) bonded to the substrate 110. In addition, as shown in FIG. 3, the transparent display apparatus 100 according to one embodiment of the present disclosure may include an encapsulation layer 130 and a spacer 140 disposed between the substrate 110 and the opposing substrate 120. The opposing substrate 120 according to one example may include a support area SPA overlapping the spacer 140.

In the case of a general transparent display apparatus, a foreign substance may be generated due to the collapse of the cell gap between the lower substrate and the upper substrate or sagging of the substrate. Therefore, in the case of a general transparent display apparatus, pixel defects may occur due to the foreign substance.

In contrast, the transparent display apparatus 100 according to one embodiment of the present disclosure has the spacer 140 provided between the substrate 110 and the opposing substrate 120, so that the cell gap between the substrate 110 and the opposing substrate 120 does not collapse or substrate sag does not occur, and therefore foreign matter may not be generated. Therefore, the transparent display apparatus 100 according to one embodiment of the present disclosure can prevent or at least reduce pixel defects caused by foreign matter resulting from cell gap defects or substrate sagging.

The substrate 110 may include a thin film transistor, and may be a transistor array substrate, a lower substrate, a base substrate, or a first substrate. The substrate 110 may be a transparent glass substrate or a transparent plastic substrate.

The opposing substrate 120 may be bonded to the substrate 110 via an adhesive member. For example, the opposing substrate 120 may have a size smaller than that of the substrate 110 and may be bonded to the remaining portion except the pad area of the substrate 110. The opposing substrate 120 may be an upper substrate, a second substrate, or an encapsulation substrate.

The gate driver GD supplies gate signals to the gate lines in accordance with the gate control signal input from the timing controller 190. When the source drive IC 160 is manufactured as a driving chip, the source drive IC 160 may be packaged in the flexible film 170 in a chip on film (COF) method or a chip on plastic (COP) method.

Pads such as power pads and data pads may be formed in a non-display area of a display panel. A flexible film 170 may include lines connecting the pads to a source drive IC 160 and lines connecting the pads to lines of a circuit board 180. The flexible film 170 may be attached to the pads by using an anisotropic conducting film, whereby the pads may be connected to the lines of the flexible film 170.

Referring to FIG. 1, the substrate 110 according to one example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to one example may include gate lines, data lines, pixel driving power lines, and a plurality of pixels P (shown in FIG. 2). Each of the plurality of pixels P may include a plurality of sub-pixels SP that may be defined by the gate lines and the data lines, and a transmissive area TA positioned adjacent to some or all of the plurality of subpixels SP. The transmissive area TA is an area provided to allow light to transmit front and rear surfaces of the display panel. Therefore, a user located in the direction of the front surface of the display panel may view a background or an image positioned in the direction of the rear surface of the display panel through the transmissive area TA.

Each of the plurality of sub-pixels SP may be defined as a minimum unit area in which light is actually emitted.

According to one example, at least four sub-pixels, which are provided to emit light of different colors and disposed to be adjacent to one another, among the plurality of sub-pixels SP, and one transmissive area TA constitute one unit pixel P. One transmissive area TA included in the unit pixel may be disposed to be divided into a plurality of parts. One unit pixel may include, but is not limited to, a red sub-pixel, a white sub-pixel, a blue sub-pixel, a green sub-pixel and a transmissive area TA. According to another example, three sub-pixels SP, which are provided to emit light of different colors and disposed to be adjacent to one another, among the plurality of sub-pixels SP, and one transmissive area TA constitute one unit pixel. One unit pixel may include at least one red sub-pixel, at least one green sub-pixel, at least one blue sub-pixel and one transmissive area TA, but is not limited thereto.

Each of the plurality of sub-pixels SP may include a thin film transistor and a light emitting element connected to the thin film transistor. The sub-pixel may include a light emitting layer (or an organic light emitting layer) interposed between a first electrode and a second electrode.

The light emitting layer disposed in each of the plurality of sub-pixels SP may individually emit light of different colors or may commonly emit white light. According to one example, when the light emitting layer of each of the plurality of sub-pixels SP commonly emits white light, each of the red sub-pixel, the green sub-pixel and the blue sub-pixel may include a color filter (or a wavelength conversion member) for converting the white light into light of different colors. In this case, the white sub-pixel according to one example may not include a color filter. The color filter CF, according to one example, can include a blue color filter CF1, a green color filter CF2, and a red color filter CF3.

In the transparent display apparatus 100 according to one embodiment of the present disclosure, an area in which a red color filter CF3 is provided may be a red sub-pixel SP1, an area in which a blue color filter CF1 is provided may be a blue sub-pixel SP3, an area in which a green color filter CF2 is provided may be a green sub-pixel SP4, and an area in which a color filter is not provided may be a white sub-pixel SP2. In the present disclosure, the red sub-pixel SP1 may be expressed as a first sub-pixel provided to emit red light, the blue sub-pixel SP3 may be represented as a third sub-pixel provided to emit blue light, the green sub-pixel SP4 may be expressed as a fourth sub-pixel provided to emit green light, and the white sub-pixel SP2 may be represented as a second sub-pixel provided to emit white light.

Each of the plurality of sub-pixels SP supplies a predetermined current to the organic light emitting element in accordance with a data voltage of the data line when a gate signal is input from the gate line by using the thin film transistor. For this reason, the light emitting layer of each of the sub-pixels may emit light with a predetermined brightness in accordance with the predetermined current.

As shown in FIG. 2, the display area DA includes a transmissive area TA and a non-transmissive area. The transmissive area TA is an area through which most of light incident from the outside passes. The non-transmissive area is an area that does not transmit most of light incident from the outside. The non-transmissive area may include a light emission area EA (shown in FIG. 3) and a non-light emission area NEA (shown in FIG. 3). The non-light emission area NEA can be an area other than the light emission area EA from which light is emitted. In one example, the non-light emission area NEA can be provided on the substrate 110 between the transmissive area TA and the plurality of sub-pixels SP (or the plurality of light emission area EA), and between the plurality of sub-pixels SP (or the plurality of light emission area EA).

A plurality of lines for driving each of the plurality of pixels P may be arranged in the non-light emission area NEA and/or the light emission area EA. The plurality of lines, according to one example, can include a plurality of first signal lines SL1 and a plurality of second signal lines SL2.

The plurality of first signal lines SL1 may extend in the first direction (Y-axis direction). The plurality of first signal lines SL1 can intersect with a plurality of second signal lines SL2. Each of the plurality of first signal lines SL1 may include a pixel power line and a common power line EVSS arranged separately from the pixel power line. In one example, the common power line EVSS may partially overlap with each of the plurality of subpixels SP. For example, as shown in FIG. 2, the common power line EVSS may be arranged long in the first direction (Y-axis direction) and overlap each of the first to fourth sub-pixels SP1, SP2, SP3, SP4 arranged in the first direction (Y-axis direction).

In one embodiment, the plurality of first signal lines SL1 may further include a plurality of data lines and a reference line. The plurality of data lines may include a first data line for driving a first sub-pixel SP1, a second data line for driving a second sub-pixel SP2, a third data line for driving a third sub-pixel, and a fourth data line for driving a fourth sub-pixel SP4.

Hereinafter, when the first signal line SL1 includes a plurality of lines, one first signal line SL1 may refer to a signal line group comprised of a plurality of lines. For example, when the first signal line SL1 includes four data lines, a pixel power line, a common power line, a reference line, one first signal line SL1 may refer to a signal line group comprised of four data lines, the pixel power line, the common power line, the reference line.

The plurality of second signal lines SL2 can extend in the second direction (X-axis direction). Each of the plurality of second signal lines SL2 may include at least one gate line GL (or scan line GL).

Hereinafter, when the second signal line SL2 includes a plurality of lines, one second signal line SL2 may refer to a signal line group comprised of a plurality of lines. For example, when the second signal line SL2 includes two scan lines GL, one second signal line SL2 may refer to a signal line group comprised of two scan lines.

At least one transmissive area TA may be disposed between the second signal lines SL2 adjacent to each other. In addition, at least one transmissive area TA may be disposed between the first signal lines SL1 adjacent to each other. That is, the transmissive area TA may be surrounded by two first signal lines SL1 and two second signal lines SL2. However, it is not limited to this, and the number of signal lines surrounding the transmissive area TA may change depending on the line layout structure.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA.

Meanwhile, as shown in FIG. 1, the transparent display apparatus 100 according to one embodiment of the present disclosure may further include a dam DM. The dam DM is for preventing moisture and/or oxygen from penetrating into the display area (DA). The dam DM according to one example may be placed to surround the display area DA. For example, the dam DM may be placed in a non-display area NDA. As shown in FIG. 1, the dam DM may be positioned closer to the edge (or end) of the substrate 110 than the gate driver GD. Accordingly, the dam DM may be positioned along the edge of the substrate 110. Since the substrate 110 is bonded to the opposing substrate 120, the dam DM can be placed along the edge of the opposing substrate 120. As a result, the dam DM can be placed at the edge of each of the substrate 110 and the opposing substrate 120.

Referring to FIG. 1, the transparent display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. The non-display area NDA can include a first non-display area NDA1, a second non-display area NDA2, a third non-display area NDA3, and a fourth non-display area NDA4. The pad portion PA according to one example can be disposed in the first non-display area NDA1.

The gate driver GD supplies gate signals to the gate lines in accordance with the gate control signal input from the timing controller 190. The gate driver GD may be formed on one side of the display area DA of the display panel or on the non-display area NDA outside both sides of the display area DA in a gate driver in panel (GIP) method as shown in FIG. 1. Alternatively, the gate driver GD may be manufactured as a driving chip, packaged in a flexible film and attached to the non-display area NDA outside one side or both sides of the display area DA of the display panel by a tape automated bonding (TAB) method.

The plurality of gate drivers GD may be separately disposed on a left side of the display area DA, that is, the second non-display area NDA2 and a right side of the display area DA, that is, the third non-display area NDA3. According to one example, the plurality of gate drivers GD may be connected to the plurality of pixels P and the plurality of second signal lines SL2 for supplying signals to the plurality of pixels P. The plurality of second signal lines SL2 may include at least one signal line for supplying a signal for driving the pixel P.

The plurality of first signal lines SL1 may extend in the first direction (Y-axis direction). The plurality of first signal lines SL1 may cross the plurality of second signal lines SL2. The plurality of first signal lines may include a pixel power line and at least one data line to supply a data voltage to the pixel P. Each of the plurality of first signal lines SL1 may be connected to at least one of a plurality of pads, a pixel power shorting bar VDDB or a common power shorting bar VSSB. The pixel power shorting bar VDDB and the common power shorting bar VSSB may be disposed in the fourth non-display area NDA4 that is disposed to face the pad area PA based on the display area DA.

The pixels are provided to overlap at least one of the first signal line SL1 or the second signal line SL2 and emit predetermined light to display an image. The light emission area EA (shown in FIG. 3) may correspond to an area, which emits light, in the pixel P.

Each of the red sub-pixel SP1 (or first sub-pixel SP1), the white sub-pixel SP2 (or second sub-pixel SP2), the blue sub-pixel SP3 (or third sub-pixel SP3), and the green sub-pixel SP4 (or fourth sub-pixel SP4) can comprise at least one or more light emission areas. The at least one light emission area of each of the sub-pixels SP1, SP2, SP3, SP4 can have the same shape and size, but is not necessarily limited thereto.

Referring to FIG. 2, the first subpixel SP1, the second subpixel SP2, the third subpixel SP3, and the fourth subpixel SP4 may be arranged in a column in the first direction (Y-axis direction), and the transmissive area TA may be arranged adjacent to each of the first subpixel SP1, the second subpixel SP2, the third subpixel SP3, and the fourth subpixel SP4 in the second direction (X-axis direction). However, it is not limited to this, and the arrangement structure of the plurality of subpixels SP can be arranged in various ways depending on the circuit design. For example, the plurality of subpixels SP may include the first subpixel SP1 and the third subpixel SP3 spaced apart in the first direction (Y-axis direction), and the second subpixel SP2 and the fourth subpixel SP4 spaced apart in the second direction (X-axis direction) from each of the first subpixel SP1 and the third subpixel SP3. The transmissive area TA may be arranged adjacent to each of the second subpixel SP2 and the fourth subpixel SP4 in the second direction (X-axis direction). Hereinafter, one example in which each of the first to fourth subpixels SP1, SP2, SP3, and SP4 is arranged in a row in the first direction (Y-axis direction) as shown in FIG. 2 will be described.

FIG. 3 is a schematic cross-sectional view of the line I-I′ shown in FIG. 2 according to one embodiment of the present disclosure.

Referring to FIG. 3, the transparent display apparatus 100 according to one embodiment of the present disclosure may have a non-light emission area NEA provided between the transmissive area TA and the plurality of subpixels SP1, SP2, SP3, SP4 (or the plurality of light emission areas EA) on a substrate 110. In addition, the transparent display apparatus 100 according to one embodiment of the present disclosure may have the non-light emission area NEA partially provided in the transmissive area TA. For example, the non-light emission area NEA may be formed at a position corresponding to the planarization layer 150 (or island OC) on an auxiliary line SLN in the transmissive area TA.

The non-light emission area NEA may refer to an area that is provided in the display area DA and does not emit light and may be expressed as a dead zone because it does not emit light. The dead zone according to one example may be an area in which a black matrix and/or a bank is provided, but is not limited thereto, and may refer to an area in which light is not emitted.

The non-light emission area NEA and/or the light emission area EA can have the plurality of lines, for example, first signal lines SL1 and second signal lines SL2 can be disposed. The first signal lines SL1 according to one example can include a pixel power line, a common power line EVSS, a reference line, and the plurality of data lines, which are extending in the first direction (Y-axis direction). The second signal lines SL2 according to one example can include the gate line GL disposed extending in the second direction (X-axis direction).

The transparent display apparatus 100 according to one embodiment of the present disclosure may include an encapsulation layer 130 and a spacer 140.

According to one example, the encapsulation layer 130 may be provided to partially cover the opposing substrate 120. For example, the encapsulation layer 130 may be provided on the front surface of the opposing substrate 120 to partially contact the opposing substrate 120 and cover at least one color filter CF. Accordingly, the encapsulation layer 130 can prevent or at least reduce at least one color filter CF and a black matrix BM from being torn off or lifted off from the opposing substrate 120. Since the encapsulation layer 130 is provided on the front surface (or the front surface excluding a part) of the opposing substrate 120, it can be expressed in terms of an upper encapsulation layer 130.

Meanwhile, the encapsulation layer 130 may be provided to cover the color filter CF and the black matrix BM in the light emission area EA and the non-light emission area NEA adjacent to the light-emission area EA on the opposing substrate 120. However, the color filter CF and the black matrix BM arranged in the non-light emission area NEA of the transmissive area TA may be provided to be covered or not covered by the encapsulation layer 130 depending on the design. The color filter CF and the black matrix BM arranged in the transmissive area TA can form a support (or a part of the support) that maintains a gap between the substrate 110 and the opposing substrate 120. When the encapsulation layer 130 is provided to cover at least a portion of the color filter CF and the black matrix BM arranged in the transmissive area TA, the encapsulation layer 130 covering the color filter CF and the black matrix BM of the transmissive area TA can form a support (or a portion of the support) that maintains the gap between the substrate 110 and the opposing substrate 120.

In the transparent display apparatus 100 according to one embodiment of the present disclosure, the encapsulation layer 130 may be formed of an inorganic material. Since the encapsulation layer 130 is formed of an inorganic material, the thickness may be thinner than in the case where the encapsulation layer is formed of an organic material. Since the encapsulation layer 130 can be provided on the front surface (or the front surface except for a part) of the opposing substrate 120, if the encapsulation layer 130 is provided with an inorganic material, the gap between the light-emitting element layer E (shown in FIG. 3) and the encapsulation layer 130 in the light emission area EA can increase. Accordingly, since the transparent display apparatus 100 according to one embodiment of the present disclosure comprises the encapsulation layer 130 made of an inorganic material, the thickness of the encapsulation layer 130 can be reduced compared to a case where the encapsulation layer is made of an organic material, and thus the cell gap (or interval) between the light-emitting element layer E in the light emission area EA and the encapsulation layer 130 in the light emission area EA can be increased.

Meanwhile, in the case of a general transparent display apparatus, since the encapsulation layer on the opposing substrate is made of an organic material, the thickness of the encapsulation layer can be thick. Therefore, in the case of the general transparent display apparatus, there is a problem that the viewing angle narrows because the angle at which light emitted from the light emitting layer is refracted by the encapsulation layer of the organic material becomes large due to the thick thickness of the encapsulation layer made of organic material.

In contrast, the transparent display apparatus 100 according to one embodiment of the present disclosure has the encapsulation layer 130 made of an inorganic material, so that the encapsulation layer 130 can be provided thinly. Therefore, in the transparent display apparatus 100 according to one embodiment of the present disclosure, even if light emitted from the light emitting element layer E is incident on the encapsulation layer 130, due to the thin thickness of the encapsulation layer 130, the light is not refracted or is refracted at a minimal angle, so that the viewing angle can be maintained without narrowing.

In addition, since the transparent display apparatus 100 according to one embodiment of the present disclosure has a thin encapsulation layer 130, the cell gap (or interval) between the light-emitting element layer E in the light emission area EA and the encapsulation layer 130 in the light emission area EA can be increased, so that the viewing angle can be improved.

In addition, since the transparent display apparatus 100 according to one embodiment of the present disclosure has a thin encapsulation layer 130 formed of an inorganic material, the cell gap (or interval) between the light-emitting element layer E and the encapsulation layer 130 can be increased, so that even if the opposing substrate 120 or substrate 110 is pressed by an external force, the light-emitting element layer E and the encapsulation layer 130 may not come into contact, thereby preventing or at least reducing a dark spot defect.

Meanwhile, in the transparent display apparatus 100 according to one embodiment of the present disclosure, since the encapsulation layer 130 is formed of an inorganic material, it may also be expressed as the term of an inorganic encapsulation layer 130. Accordingly, in the present disclosure, the encapsulation layer 130 may be an upper encapsulation layer formed on the opposing substrate 120 and may be the inorganic encapsulation layer formed of an inorganic material.

Referring again to FIG. 3, the spacer 140 may be placed between the opposing substrate 120 and the substrate 110. In one example, the spacer 140 may be placed so as to overlap the transmissive area TA. The spacer 140 may be a support (or a part of the support) for maintaining a gap between the opposing substrate 120 and the substrate 110. For example, the spacer 140 may be arranged to overlap a black matrix BM and a color filter structure CFS arranged in the transmissive area TA. Additionally, the spacer 140 may be arranged to overlap with an inorganic film layer IL, a planarization layer 150, and a pattern structure PS arranged in the transmissive area TA on the substrate 110. Therefore, the spacer 140 can function as the support (or a part of the support) that maintains the gap between the opposing substrate 120 and the substrate 110. With reference to FIG. 3, the spacer 140 may include an upper surface 140a positioned at the uppermost side in the third direction (Z-axis direction), a lower surface 140c positioned closer to the substrate 110 than the upper surface 140a, and a side surface 140b connected to each of the upper surface 140a and the lower surface 140c.

Meanwhile, as illustrated in FIG. 3, the spacer 140 may be placed in a transmissive area TA. The transparent display apparatus 100 according to one embodiment of the present disclosure may include at least one transmissive area TA for each of a plurality of pixels P. Accordingly, since the transparent display apparatus 100 according to one embodiment of the present disclosure may be provided with each of a plurality of spacers 140 in each of a plurality of transmissive areas TA, the cell gap between the substrate 110 and the opposing substrate 120 may be firmly maintained, so that not only may the defect rate be reduced, but also the robustness against external force may be improved.

In a transparent display apparatus 100 according to one embodiment of the present disclosure, the opposing substrate 120 may include a support area SPA overlapping with the spacer 140. As described above, the opposing substrate 120 and the substrate 110 can be spaced apart by the black matrix BM, the color filter structure CFS, the spacer 140, the pattern structure PS, the planarization layer 150, and the inorganic film layer IL arranged in the transmissive area TA. Accordingly, as shown in FIG. 3, a portion of the transmissive area TA may be provided with a support area SPA that supports the opposing substrate 120 and the substrate 110.

In a transparent display apparatus 100 according to one embodiment of the present disclosure, the encapsulation layer 130 may be disconnected in at least a portion of the support area SPA.

If the encapsulation layer is not cut off and covers the entire front (or entirety) of the opposing substrate, a crack may occur in the support area that supports the opposing substrate when an impact occurs due to an external force, and this crack may propagate to the light-emission area through the encapsulation layer, allowing moisture and oxygen to penetrate into the light-emitting element. Therefore, when the encapsulation layer is provided over the entire opposing substrate, there is a problem that crack propagation through the encapsulation layer causes moisture penetration into the light-emitting element (or light-emitting element layer E), thereby shortening the lifespan of the light-emitting element.

Therefore, the transparent display apparatus 100 according to one embodiment of the present disclosure is provided such that the encapsulation layer 130 is disconnected at least in a part of the support area SPA, so that even if an impact occurs due to an external force, crack propagation through the encapsulation layer 130 can be blocked. Therefore, the transparent display apparatus 100 according to one embodiment of the present disclosure is provided so that crack propagation through the encapsulation layer 130 is blocked, so that the crack does not propagate to the light emission area EA (or the light-emitting element layer E), thereby preventing moisture penetration into the light-emitting element (or the light-emitting element layer E).

Furthermore, since the transparent display apparatus 100 according to one embodiment of the present disclosure is provided so that crack propagation is blocked due to the disconnection of the encapsulation layer 130, the lifespan of the light-emitting element (or the light-emitting element layer E) can be improved compared to a case where the encapsulation layer is provided on the entirety (or the entirety of one side) of the opposing substrate, and thus the light-emitting element (or the light-emitting element layer E) can be driven with low power compared to the entire lifespan, so that power consumption can be reduced.

Referring to FIG. 3, the transparent display apparatus 100 according to one embodiment of the present disclosure may further include a black matrix BM disposed on the opposing substrate 120 and overlapping the support area SPA, and a color filter structure CFS disposed on the black matrix BM.

The black matrix BM superimposed on the support area SPA supports the opposing substrate 120 and the substrate 110, and thus can be distinguished from the black matrix BM overlapping the non-light emission area NEA adjacent to the light emission area EA. The black matrix BM overlapping the non-light emission area NEA adjacent to the light emission area EA is intended to prevent or at least reduce color mixing between the plurality of subpixels SP. The black matrix BM overlapping the support area SPA can be formed together on one side (or lower side) of the opposing substrate 120 when the black matrix BM overlapping the non-light emission area NEA adjacent to the light emission area EA is formed.

The color filter structure CFS according to one example may be formed of at least one color filter. For example, the color filter structure CFS may be formed by overlapping the first color filter CF1 and the second color filter CF2, as shown in FIG. 3. Since the first color filter CF1 and the second color filter CF2 are provided in an overlapping manner, a thickness of the color filter structure CFS can be sufficiently secured. Accordingly, the color filter structure CFS can function as a support (or a part of the support) that maintains the gap between the opposing substrate 120 and the substrate 110.

Hereinafter, with reference to FIG. 3, the structure of each of the plurality of sub-pixels SPs will be described in detail.

Referring to FIG. 3, a transparent display apparatus 100 according to one embodiment of the present disclosure can include a buffer layer BL, a plurality of inorganic film layers 111, a thin film transistor 112, an overcoat layer 113, a pixel electrode 114, a bank 115, an organic light emitting layer 116, an opposing electrode 117, a lower encapsulation layer 118, a filling layer 119, a color filter CF, a black matrix BM., and an encapsulation layer 130 (or an upper encapsulation layer 130).

In more detail, each of the subpixels SP according to one embodiment may include a plurality of inorganic film layers 111 provided on an upper surface of a buffer layer BL, including a gate insulating layer 111a, an interlayer insulating layer 111b and a passivation layer 111c, an overcoat layer 113 provided on the plurality of inorganic film layers 111, a pixel electrode 114 provided on the overcoat layer 113, a bank 115 covering an edge of the pixel electrode 114, an organic light emitting layer 116 on the pixel electrode 114 and the bank 115, an opposing electrode 117 on the organic light emitting layer 116, a lower encapsulation layer 118 on the opposing electrode 117, a filling layer 119 on the lower encapsulation layer 118, the color filter CF and the black matrix BM on the filling layer 119, a encapsulation layer 130 (or an upper encapsulation layer 130) covering the color filter CF and the black matrix BM. The plurality of inorganic film layers 111 may include an inorganic film layer IL disposed on an auxiliary line SLN of the transmissive area TA. The inorganic film layer IL may be formed of the same material as the interlayer insulating layer 111b and the passivation layer 111c. In addition, the inorganic film layer IL may be formed on the same layer as the interlayer insulating layer 111b and the passivation layer 111c.

The thin film transistor 112 for driving the subpixel SP may be disposed on the plurality of inorganic film layers 111. The plurality of inorganic film layers 111 may be expressed as the term of a circuit element layer. The buffer layer BL may be included in the plurality of inorganic film layers 111 together with the gate insulating layer 111a, the interlayer insulating layer 111b and the passivation layer 111c. The pixel electrode 114, the organic light emitting layer 116 and the opposing electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The common power line EVSS and the auxiliary line SLN can be placed on the buffer layer BL.

The common power line EVSS may be spaced apart from the thin film transistor 112 and may be arranged to overlap the light emission area EA and/or the non-light emission area NEA of each of the plurality of subpixels SP. The auxiliary line SLN can be connected and arranged to the common power line EVSS. Accordingly, the auxiliary line SLN can receive a common voltage from the common power line EVSS. According to one example, the auxiliary line SLN may be formed together with the common power line EVSS. The buffer layer BL may also serve to block a material contained in the substrate 110 from diffusing into the transistor layer during a high-temperature process during the manufacturing process of the thin film transistor. Optionally, the buffer layer BL may be omitted in some cases.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape on the channel area of the active layer 112a or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. As in FIG. 3, the interlayer insulating layer 111b may be formed in an entire light emission area, in which light is emitted to the subpixel SP. However, embodiments of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 may further include a light shielding layer LS provided below the active layer 112a of at least one of the thin film transistor 112, the first switching thin film transistor or the second switching thin film transistor. The light shielding layer LS may be disposed between the substrate 110 and the active layer 112a to shield light incident on the active layer 112a through the substrate 110, thereby minimizing a change in the threshold voltage of the transistor due to external light. Also, since the light shielding layer LS is provided between the substrate 110 and the active layer 112a, the thin film transistor 112 may be prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL. The passivation layer 111c may be formed over the circuit area and the light emission area. The passivation layer 111c may be omitted.

The overcoat layer 113 may be provided on the substrate 110 to cover the passivation layer 111c. When the passivation layer 111c is omitted, the overcoat layer 113 may be provided on the substrate 110 to cover the circuit area (or the thin film transistor 112). The overcoat layer 113 may be formed in the circuit area CA in which the thin film transistor 112 is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

On the other hand, the upper surface of the overcoat layer 113 can be provided flatly. Accordingly, the pixel electrodes 114 on the overcoat layer 113 can also be provided flatly, and the organic light emitting layer 116 and the opposing electrode 117 formed thereon can also be provided flatly. Since the pixel electrode 114, the organic light emitting layer 116, the opposing electrode 117, that is, the light emitting element layer E is provided to be flat in the light emission area EA, a thickness of each of the pixel electrode 114, the organic light emitting layer 116 and the opposing electrode 117 in the light emission area EA may be uniformly formed. Therefore, the organic light emitting layer 116 may be uniformly emitted without deviation in the light emission area EA.

The pixel electrodes 114 according to one example can be formed on the overcoat layer 113. The pixel electrode 114 may be connected to a drain electrode or a source electrode of the thin film transistor 112 through a contact hole passing through the overcoat layer 113 and the passivation layer 111c. The one edge portion of the pixel electrode 114 may be covered by the bank 115. The pixel electrode 114 may be made of at least one of a transparent metal material or a semi-transmissive metal material.

Since the transparent display apparatus 100 according to one embodiment of the present disclosure is top-emission type, the pixel electrodes 114 can be made of a highly reflective metallic material or a stacked structure of a highly reflective metallic material and a transparent metallic material. For example, the pixel electrode 114 may be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy may be an alloy such as silver (Ag), palladium (Pd), and copper (Cu).

Meanwhile, the material constituting the pixel electrode 114 may include MoTi. The pixel electrode 114 may be a first electrode or an anode electrode.

The bank 115 may be an area, which does not emit light, and disposed on one side of the light emission area EA of each of the plurality of sub-pixels SP. For example, the bank 115 may be disposed in the non-light emission area NEA. The bank 115 may be formed to cover a portion where the edge of the pixel electrode 114. Accordingly, the bank 115 may prevent the pixel electrode 114 from contacting the opposing electrode 117 at the edge of the pixel electrode 114. The exposed portion of the pixel electrode 114 that is not covered by the bank 115 may be included in the light emitting portion (or light emission area EA).

After the bank 115 is formed, an organic light emitting layer 116 may be formed to cover the pixel electrodes 114 and the bank 115. Thus, the bank 115 may be provided between the pixel electrodes 114 and the organic light emitting layer 116. The bank 115 may be expressed in terms of a pixel-defining membrane. The bank 115 according to one example may comprise organic material and/or inorganic material.

Referring again back to FIG. 3, the organic light emitting layer 116 may be formed on the pixel electrodes 114 and the bank 115. According to one example, the organic light emitting layer 116 may be disposed in the light emission area EA and the non-light emission area NEA. The organic light emitting layer 116 may be provided between the pixel electrode 114 and the opposing electrode 117. Thus, when a voltage is applied to each of the pixel electrode 114 and the opposing electrode 117, an electric field is formed between the pixel electrode 114 and the opposing electrode 117. Therefore, the organic light emitting layer 116 may emit light. The organic light emitting layer 116 may be formed of a plurality of subpixels SP and a common layer provided on the bank 115.

The organic light emitting layer 116 according to an embodiment may be provided to emit white light. The organic light emitting layer 116 may include a plurality of stacks which emit light of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML (B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML (YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The opposing electrode 117 may be formed on the organic light emitting layer 116. The opposing electrode 117 may be disposed in the light emission area EA and the non-light emission area NEA. The opposing electrode 117 according to one example may include a metal material. The opposing electrode 117 may reflect the light emitted from the organic light emitting layer 116 in the plurality of subpixels SP toward the lower surface of the substrate 110. Therefore, the display apparatus 100 according to one embodiment of the present disclosure may be implemented as a bottom emission type display apparatus.

Since the transparent display apparatus 100 according to one embodiment of the present disclosure is top-emission type, the opposing electrodes 117 can be formed of a transparent conductive material TCO such as ITO, IZO, that is capable of transmitting light or a semi-transmissive conductive material TMCM such as magnesium (Mg), silver (Ag), or an alloy of magnesium (Mg) and silver (Ag). Such opposing electrodes 117 can be referred in terms of second electrodes, cathode electrodes.

Meanwhile, referring to FIG. 3, the opposing electrode 117 is positioned under the lower encapsulation layer 118 and can be in contact with the auxiliary line SLN at an undercut portion UC under the planarization layer 150. Since the organic light-emitting layer 116 and the opposing electrode 117 are sequentially deposited on the entire surface of the substrate 110 after the undercut portion UC is formed, the organic light-emitting layer 116 and the opposing electrode 117 can be disconnected by the undercut portion UC. Accordingly, an end of the opposing electrode 117 extended from the light emitting element layer E can contact an upper surface of the auxiliary line SLN in the undercut portion UC formed in the transmissive area TA. Therefore, the opposing electrode 117 can receive a common voltage from the auxiliary line SLN. Accordingly, in the transparent display apparatus 100 according to one embodiment of the present disclosure, the opposing electrode 117 and the auxiliary line SLN can be in contact with each of the plurality of transmissive areas TA arranged in the display area DA, so that the voltage drop in a central portion of the display panel can be minimized or prevented.

The lower encapsulation layer 118 is formed on the opposing electrode 117. According to one example, the lower encapsulation layer 118 serves to prevent oxygen or moisture from penetrating into the organic light-emitting layer 116 and the opposing electrode 117. To this end, the lower encapsulation layer 118 may be provided to seal the light emitting element layer E in each of the plurality of subpixels SP. For example, the lower encapsulation layer 118 may be provided on the substrate 110 to cover the light emission area EA and the non-light emission area NEA. In addition, the lower encapsulation layer 118 may also be provided in the transmissive area TA. That is, the lower encapsulation layer 118 may be deposited on the entire surface of the substrate 110. The lower encapsulation layer 118 according to one example may be provided with an inorganic material, but is not limited thereto, and may be provided with an organic material or may be provided with a structure in which an organic material and an inorganic material are laminated. The lower encapsulation layer 118 may be interrupted by the undercut portion UC. In one example, the undercut portion UC may be partially disposed under the planarization layer 150 in the transmissive area TA. For example, as shown in FIG. 3, the undercut portion UC may be disposed adjacent to the inorganic film layer IL on the auxiliary line SLN. The undercut portion UC can be formed by partially etching the interlayer insulating layer 111b and the passivation layer 111c on the auxiliary line SLN. Accordingly, as shown in FIG. 3, an island-shaped inorganic film layer IL and an undercut portion UC positioned adjacent to the inorganic film layer IL can be formed on the auxiliary line SLN.

The filling layer 119 is formed on the lower encapsulation layer 118. The filling layer 119 can play a role in preventing or at least reducing oxygen or moisture from penetrating into the organic light-emitting layer 116 and the opposing electrode 117, similar to the lower encapsulation layer 118. The filling layer 119 according to one example can be configured to include a getter capable of absorbing oxygen or moisture. Alternatively, the filling layer 119 may be provided with a plurality of layers including at least one inorganic film layer and at least one organic film layer.

On the other hand, as shown in FIG. 3, the filling layer 119 can be disposed in the light emission area EA and in the non-light emission area NEA. The filling layer 119 can be disposed between the lower encapsulation layer 118 and the opposing substrate 120.

A color filter CF and a black matrix BM can be disposed between the filling layer 119 and the opposing substrate 120. As mentioned above, the white light emitting portion SP2 cannot be provided with a color filter since the organic light emitting layer 116 emits white light. On the other hand, the red sub-pixel SP1 can be provided with the third color filter CF3 (or red color filter CF3) between the filling layer 119 and the opposing substrate 120. The blue sub-pixel SP3 can be provided with the first color filter CF1 (or blue color filter CF1) between the filling layer 119 and the opposing substrate 120. The green sub-pixel SP4 can be provided with the second color filter CF2 (or green color filter CF2) between the filling layer 119 and the opposing substrate 120. As shown in FIG. 3, at least one color filter CF can be placed on the black matrix BM in the transmissive area TA.

On the other hand, the black matrix BM can be provided between the plurality of sub-pixels SP1, SP2, SP3, SP4 to prevent or at least reduce color mixing and/or light leakage. The black matrix BM can comprise a black colored material and can be disposed overlapping the bank 115. The area provided with the black matrix BM and/or the bank 115 can be a dead zone or the non-light emission area. The black matrix BM according to one example can be formed on an opposing substrate 120 to overlap at least a portion of the bank 115, thereby reducing the cell gap between the organic light emitting layer 116 and the opposing substrate 120 to prevent mixing of sub-pixels.

In addition, as shown in FIG. 3, the black matrix BM according to one example partially overlaps at least one color filter CF and the planarization layer 150 and is positioned between the spacer 140 and the opposing substrate 120, thereby functioning as a support that maintains the gap between the substrate 110 and the opposing substrate 120.

The encapsulation layer 130 (or upper encapsulation layer 130) may be provided to cover the color filter CF in the light-emission area EA and the black matrix BM in the non-light emission area NEA adjacent to the light emission area EA. In addition, the encapsulation layer 130 (or upper encapsulation layer 130) may be provided on the front surface of the opposing substrate 120 so as to partially contact the opposing substrate 120.

Meanwhile, the color filter CF overlapping the light-emission area EA and the black matrix BM overlapping the non-light emission area NEA adjacent to the light emission area EA can be peeled off from the opposing substrate 120 during a cleaning process to remove impurities after being formed on the opposing substrate 120. However, in the transparent display apparatus 100 according to one embodiment of the present disclosure, the encapsulation layer 130 (or the upper encapsulation layer 130) is provided to cover the color filter CF overlapped in the light emission area EA and the black matrix BM overlapped in the non-light emission area NEA adjacent to the light emission area EA, so that the color filter CF overlapped in the light emission area EA and the black matrix BM overlapped in the non-light emission area NEA adjacent to the light emission area EA can be prevented from being torn off from the opposing substrate 120 during a cleaning process.

Referring to FIG. 3, the transparent display apparatus 100 according to one embodiment of the present disclosure may include the auxiliary line SLN, the planarization layer 150, the inorganic film layer IL, and the undercut portion UC.

As shown in FIG. 3, the auxiliary line SLN may be arranged on the substrate 110. According to one example, the auxiliary line SLN may partially overlap the transmissive area TA. The auxiliary line SLN is for supplying a common voltage (or common power) to the opposing electrode 117. Accordingly, as shown in FIG. 3, the auxiliary line SLN extends from the transmissive area TA toward one of the plurality of sub-pixels SP (e.g., the third sub-pixel SP3) and connected to the common power line EVSS. And, the opposing electrode 117 can be connected to the auxiliary line SLN at the undercut portion UC. Since the auxiliary line SLN is configured to be connected to the common power line EVSS, it can be expressed in terms of a branch line of the common power line.

For example, in the case of a general large-area transparent display apparatus, a voltage drop may occur when a common voltage supplied from an edge portion of the display panel is applied to the center portion of the display panel. Therefore, the general large-area transparent display apparatus has a problem in that the brightness of the image emitted from the edge and center of the display panel is uneven. In addition, the general large-area transparent display apparatus has to drive the display panel at high power to solve the problem of uneven brightness of the image as described above, so there is a problem in that the overall power consumption increases.

However, in the transparent display apparatus 100 according to one embodiment of the present disclosure, the auxiliary line SLN is arranged to overlap the transmissive area TA included in the plurality of pixels P, so that the opposing electrode 117 can receive a common voltage through the auxiliary line SLN even in the central portion of the display panel. Accordingly, the transparent display apparatus 100 according to one embodiment of the present disclosure is provided so that the common voltage difference between the edge portion and the center portion of the display panel is small or does not occur, so that the brightness of the image emitted from the edge portion and the center portion of the display panel can be provided uniformly.

In addition, since the transparent display apparatus 100 according to one embodiment of the present disclosure is provided such that the opposing electrode 117 and the auxiliary line SLN are in contact at the undercut portion UC in the transmissive area TA, the voltage drop at the center portion of the display panel can be prevented or at least reduced, so that the brightness of the edge portion and the center portion of the display panel can be made uniform with low power, and thus the overall power consumption reduction can be maximized.

The planarization layer 150 may be placed on the auxiliary line SLN. According to one example, the planarization layer 150 is for forming the undercut portion UC. Accordingly, the planarization layer 150 may be placed on the auxiliary line SLN while having a predetermined width and thickness. For example, the planarization layer 150 may be provided in a tapered shape. This planarization layer 150 may be formed of the same material as the overcoat layer 113 in the light emission area EA. In addition, the planarization layer 150 may be formed together with the overcoat layer 113, and thus may be provided in the same layer as the overcoat layer 113.

The undercut portion UC is for disconnecting the lower encapsulation layer 118. The undercut portion UC may mean a plurality of spaces formed between the auxiliary line SLN and the planarization layer 150. The planarization layer 150 may be arranged spaced apart from the auxiliary line SLN in the third direction (Z-axis direction). For example, since the inorganic film layer IL may be arranged between the planarization layer 150 and the auxiliary line SLN, the planarization layer 150 may be arranged spaced apart from the auxiliary line SLN in the third direction (Z-axis direction). As shown in FIG. 3, the undercut portion UC may be provided adjacent to both sides of the inorganic film layer IL, such as along the Y-axis direction.

Meanwhile, in the transparent display apparatus 100 according to one embodiment of the present disclosure, the planarization layer 150 (or island OC) on the auxiliary line SLN may function as a support that supports the opposing substrate (or the upper substrate). For example, as shown in FIG. 3, the planarization layer 150 on the auxiliary line SLN may function as a support that maintains a gap between the substrate 110 and the opposing substrate 120 together with the inorganic film layer IL, the pattern structure PS, the spacer 140, at least one color filter CF, and the black matrix BM. Therefore, the transparent display apparatus 100 according to one embodiment of the present disclosure can have improved robustness against external impact (or external force) without a separate support.

In addition, when the transparent display apparatus 100 according to one embodiment of the present disclosure is implemented as a large-area transparent display apparatus, since a support is provided for each of a plurality of transmissive areas TA, the opposing substrate (or the upper substrate) can be prevented from being tilted toward the substrate 110 (or the lower substrate 110), and thus the defect rate can be reduced.

Referring to FIG. 3, the inorganic film layer IL may be placed between the planarization layer 150 and the auxiliary line SLN. According to one example, the inorganic film layer IL may include an interlayer insulating layer 111b and a passivation layer 111c. As shown in FIG. 3, each of the interlayer insulating layer 111b and the passivation layer 111c of the inorganic film layer IL can be formed in the same layer with the same material as each of the interlayer insulating layer 111b and the passivation layer 111c in the light emission area EA. The interlayer insulating layer 111b and the passivation layer 111c of the inorganic layer IL can be provided in an island shape on the auxiliary line SLN as the undercut portion UC is formed. In addition, since the undercut portion UC is formed by etching the interlayer insulating layer 111b and the passivation layer 111c at the lower edge of the planarization layer 150, the inorganic film layer IL can be provided with a narrower width than the planarization layer 150.

The planarization layer 150 may be spaced apart from the overcoat layer 113 overlapping the light emission area EA. For example, the planarization layer 150 may be arranged to overlap the transmissive area TA, and thus be spaced apart from the overcoat layer 113 in the light emission area EA. The planarization layer 150 can be formed together with the overcoat layer 113 using the same material and process. Accordingly, the planarization layer 150 can be placed on the same layer as the overcoat layer 113. For example, the planarization layer 150 may be placed on the passivation layer 111c of the inorganic film layer IL. In this disclosure, different terms and drawing symbols are used to distinguish the planarization layer 150 from the overcoat layer 113. Since the planarization layer 150 is provided in the form of an island spaced apart from the overcoat layer 113, it can be expressed by the term island OC.

According to one example, an undercut portion UC may be partially disposed between the planarization layer 150 and the auxiliary line SLN. The undercut portion UC may be formed between the auxiliary line SLN and the planarization layer 150 so that the lower encapsulation layer 118 is disconnected. The undercut portion UC may be formed by partially etching the interlayer insulating layer 111b and the passivation layer 111c between the planarization layer 150 and the auxiliary line SLN. Accordingly, a predetermined space may be formed on the left and right sides of each of the interlayer insulating layer 111b and the passivation layer 111c on an upper surface of the auxiliary line SLN based on FIG. 3. Accordingly, in the transparent display apparatus 100 according to one embodiment of the present disclosure, the undercut portion UC is provided on both sides of the inorganic film layer IL located under the planarization layer 150, so that the lower encapsulation layer 118 may be disconnected.

According to one embodiment of the present disclosure, a transparent display apparatus 100 may be provided so that even if an external impact is transmitted to the lower encapsulation layer 118 on the planarization layer 150 through the spacer 140 and a crack occurs, the crack does not propagate to the lower encapsulation layer 118 covering the light emitting element layer E of each of the plurality of subpixels SP through the lower encapsulation layer 118 because the lower encapsulation layer 118 is disconnected by the undercut portion UC. That is, since the transparent display apparatus 100 according to one embodiment of the present disclosure can have the lower encapsulation layer 118 disconnected through the undercut portion UC, crack propagation through the lower encapsulation layer 118 can be blocked.

Furthermore, in the transparent display apparatus 100 according to one embodiment of the present disclosure, since cracks do not propagate in the lower encapsulation layer 118 covering the light-emitting elements (or light-emitting element layers E) of each of the plurality of subpixels SP, the lower encapsulation layer 118 can maintain a state of sealing the light-emitting elements (or light-emitting element layers E), and thus moisture penetration into the light-emitting elements (or light-emitting element layers E) can be prevented or at least reduced. The light-emitting element layers E may mean light-emitting elements that emit light in each of the plurality of subpixels SP.

Referring to FIG. 3, a transparent display apparatus 100 according to one embodiment of the present disclosure may further include a pattern structure PS disposed on an upper surface of a planarization layer 150.

The pattern structure PS according to one example may be placed between the planarization layer 150 and the spacer 140. Therefore, the pattern structure PS may function as a support supporting the substrate 110 and the opposing substrate 120. The pattern structure PS may be formed together with the bank 115 on the upper surface of the overcoat layer 113. Therefore, the pattern structure PS can be placed on the same layer as the bank 115. In this case, the pattern structure PS can be formed of the same material as the bank 115. Therefore, since the transparent display apparatus 100 according to one embodiment of the present disclosure can form the pattern structure PS on the planarization layer 150 together with the bank 115 without a separate additional process, it is possible to form a support (or a part of the support) that maintains a gap between the substrate 110 and the opposing substrate 120 without an increase in cost. However, the present invention is not limited thereto, and the pattern structure PS may be formed of a different material through a different process from the bank 115.

As shown in FIG. 3, the pattern structure PS may be placed on the upper surface of the planarization layer 150. Therefore, the pattern structure PS may be covered by the organic light-emitting layer 116, the opposing electrode 117, and the lower encapsulation layer 118. The organic light-emitting layer 116, the opposing electrode 117, and the lower encapsulation layer 118 may be disconnected by the undercut portion UC. Accordingly, each of the organic light-emitting layer 116 covering the pattern structure PS, the opposing electrode 117 covering the pattern structure PS, and the lower encapsulation layer 118 covering the pattern structure PS may be provided discontinuously by being disconnected by the undercut portion UC. Therefore, each of the organic light-emitting layer 116 covering the pattern structure PS, the opposing electrode 117 covering the pattern structure PS, and the lower encapsulation layer 118 covering the pattern structure PS may be provided in an island shape.

Meanwhile, the transparent display apparatus 100 according to one embodiment of the present disclosure may have a structural feature in which an island-shaped lower encapsulation layer 118 is provided to cover a pattern structure PS, such that the lower encapsulation layer 118 covering the pattern structure PS comes into contact with a lower surface 140c of the spacer 140, as shown in FIG. 3. As shown in FIG. 3, each of the island-shaped lower encapsulation layer 118, the island-shaped opposing electrode 117, and the island-shaped organic light-emitting layer 116 located between the spacer 140 and the pattern structure PS can function as a support that maintains the gap between the opposing substrate 120 and the substrate 110.

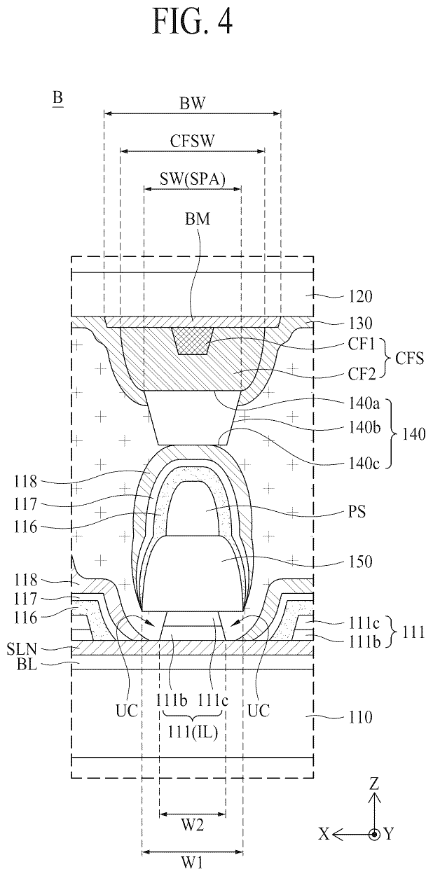

FIG. 4 is a schematic cross-sectional view of portion B of FIG. 3 according to one embodiment.

Referring to FIG. 4, the transparent display apparatus 100 according to one embodiment of the present disclosure may be provided such that a width CFSW of the color filter structure CFS is larger than a width SW of the spacer 140 and narrower than a width BW of the black matrix BM.

If the width CFSW of the color filter structure CFS in contact with the black matrix BM is wider than the width BW of the black matrix BM, light may be emitted through the color filter that does not overlap the black matrix, which may cause color mixing.

In addition, if the width CFSW of the color filter structure CFS is narrower than the width SW of the spacer 140, the supporting force of the color filter structure CFS supporting the spacer 140 becomes small, so the robustness against external impact may be reduced.

Therefore, the transparent display apparatus 100 according to one embodiment of the present disclosure is provided with the width CFSW of the color filter structure CFS that is larger than the width SW of the spacer 140 and narrower than the width BW of the black matrix BM, thereby preventing color mixing and improving robustness against external impact.

Meanwhile, in the transparent display apparatus 100 according to one embodiment of the present disclosure, an upper surface 140a of the spacer 140 may be in contact with the color filter structure CFS. This is because the color filter structure CFS is formed after the black matrix BM is formed on the opposing substrate 120 in the transmissive area TA, and then the spacer 140 is formed. And, since the encapsulation layer 130 is formed on a front surface of the opposing substrate 120 in the subsequent process, the encapsulation layer 130 can be provided to cover the black matrix BM, the color filter structure CFS, and the spacer 140 in the transmissive area TA. However, in order to block crack propagation by the encapsulation layer 130 according to one embodiment of the present disclosure, the encapsulation layer 130 covering the spacer 140 can be patterned and removed. Therefore, as shown in FIG. 4, the transparent display apparatus 100 according to one embodiment of the present disclosure may have a structural feature in which the encapsulation layer 130 covers the black matrix BM and the color filter structure CFS and is in contact with a side surface 140b of the spacer 140.

Therefore, the transparent display apparatus 100 according to one embodiment of the present disclosure is provided such that the encapsulation layer 130 is disconnected at least in a part of the support area SPA, so that even if an external impact occurs, a crack may not propagate to the light emission area EA through the encapsulation layer 130, thereby preventing moisture penetration into the light-emitting element and improving reliability.

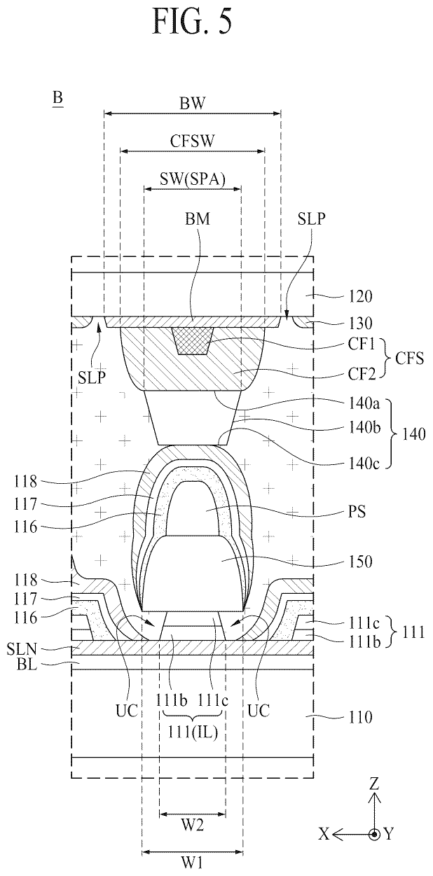

FIG. 5 is a schematic cross-sectional view showing a second example of portion B in FIG. 3 according to one embodiment.

In the case of the transparent display apparatus 100 according to FIG. 5, a structure of the encapsulation layer 130 is changed, and a slit portion SLP is added, except that it is the same as the transparent display apparatus 100 according to FIG. 1 described above. Therefore, the same drawing symbols have been assigned to the same configuration, and only the different configurations will be described hereinafter.

In the case of the transparent display apparatus according to FIG. 1, the encapsulation layer 130 is provided to be disconnected at least in a part of the support area SPA, so that the encapsulation layer 130 can come into contact with the side surface 140b of the spacer 140. Accordingly, the transparent display apparatus according to FIG. 1 can prevent or at least reduce moisture penetration into the light-emitting element and improve reliability since cracks may not propagate to the light emission area EA through the encapsulation layer 130 even if an external impact occurs.

In contrast, in the case of the transparent display apparatus according to FIG. 5, the encapsulation layer 130 may be provided so as to be disconnected with the black matrix BM therebetween. That is, the encapsulation layer 130 can be separated (or disconnected) by the black matrix BM. This is because, in the process of removing the encapsulation layer 130 covering the spacer 140, the area where the encapsulation layer 130 is removed is set to be larger than in the transparent display apparatus according to FIG. 1. Therefore, in the case of the transparent display apparatus according to FIG. 5, the encapsulation layer 130 can be disconnected with the black matrix BM therebetween. In addition, in the case of the transparent display apparatus according to FIG. 5, since a removal area of the encapsulation layer 130 is wider than that of the transparent display apparatus according to FIG. 1, the color filter structure CFS may have a structural feature in which it is not covered by the encapsulation layer 130.

Meanwhile, the transparent display apparatus 100 according to FIG. 5 may further include a slit portion SLP provided between the encapsulation layer 130 and the black matrix BM. As described above, in the case of the transparent display apparatus according to FIG. 5, since the removal area of the encapsulation layer 130 is wider than that of the transparent display apparatus according to FIG. 1, the encapsulation layer 130 may be formed apart from the black matrix BM in the transmissive area TA. Accordingly, the slit portion SLP can be formed between the black matrix BM and the encapsulation layer 130. Since the transparent display apparatus 100 according to FIG. 5 has a slit portion SLP between the encapsulation layer 130 and the black matrix BM functioning as a support, even if an external impact occurs, cracks may not propagate to the light emission area EA through the encapsulation layer 130, so that moisture penetration into the light-emitting element can be prevented, thereby improving reliability.

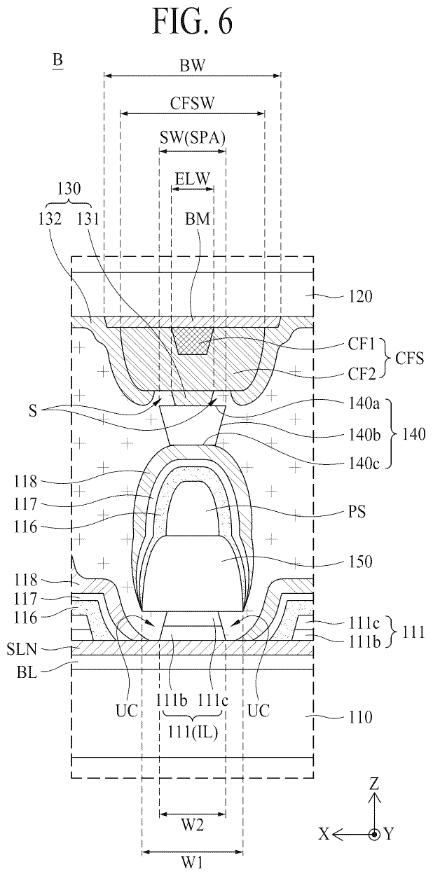

FIG. 6 is a schematic cross-sectional view showing a third example of portion B in FIG. 3 according to one embodiment.

In the case of the transparent display apparatus 100 according to FIG. 6, a structure of the encapsulation layer 130 and the spacer 140 is changed, and a space portion S is further included, except that it is the same as the transparent display apparatus 100 according to FIG. 1 described above. Therefore, the same drawing symbols have been assigned to the same configuration, and only the different configurations will be described hereinafter.

In the case of the transparent display apparatus according to the above-described FIG. 1, after the black matrix BM is formed on the opposing substrate 120 in the transmissive area TA, the color filter structure CFS, the spacer 140, and the encapsulation layer 130 are sequentially formed, and then a part of the encapsulation layer 130 can be removed. Accordingly, in the case of the transparent display apparatus according to FIG. 1, crack propagation through the encapsulation layer 130 can be blocked while having a structure in which the encapsulation layer 130 is in contact with the side surface 140b of the spacer 140.

In contrast, in the case of the transparent display apparatus according to FIG. 6, the encapsulation layer 130 may be provided to include a first encapsulation layer 131 and a second encapsulation layer 132. The first encapsulation layer 131 according to one example may be arranged between the color filter structure CFS and the spacer 140. The second encapsulation layer 132 according to one example may be arranged to be spaced apart from the first encapsulation layer 131.

In the case of the transparent display apparatus according to FIG. 6, the black matrix BM is formed on the opposing substrate 120, then the color filter structure CFS is formed, and the encapsulation layer 130 is formed on the front surface to cover the black matrix BM and the color filter structure CFS, and then the spacer 140 is formed. And, in a subsequent process, a portion of the encapsulation layer 130 between the spacer 140 and the color filter structure CFS is removed through a wet etching process. Accordingly, in the case of the transparent display apparatus according to FIG. 6, an island-shaped first encapsulation layer 131 may be formed between the color filter structure CFS and the spacer 140, and the second encapsulation layer 132 spaced apart from the first encapsulation layer 131 may be formed. In this case, the first encapsulation layer 131 may function as a support that maintains the gap between the opposing substrate 120 and the substrate 110.

Meanwhile, in the case of the transparent display apparatus according to FIG. 6, the space portion S may be formed between the first encapsulation layer 131 and the second encapsulation layer 132. Accordingly, the transparent display apparatus 100 according to FIG. 6 has the space portion S formed adjacent to the first encapsulation layer 131 that functions as a support, so that even if an external impact occurs, a crack may not propagate to the light emission area EA through the second encapsulation layer 132, thereby preventing moisture penetration into the light-emitting element, thereby improving reliability.

As described above, the space portion S can be formed by removing a portion of the encapsulation layer 130 between the spacer 140 and the color filter structure CFS through a wet etch process. Accordingly, the transparent display apparatus 100 according to FIG. 6 can have a structural feature in which a width ELW of the first encapsulation layer 131 is smaller than the width SW of the spacer 140. In addition, the transparent display apparatus 100 according to FIG. 6 may have a structural feature in which the part of the encapsulation layer 130 between the spacer 140 and the color filter structure CFS is removed to form the space portion S, so that the second encapsulation layer 132 partially covers the black matrix BM and the color filter structure CFS.

Meanwhile, in the transparent display apparatus 100 according to FIG. 6, a thickness of the encapsulation layer 130 may be provided as 3000 Å to 8000 Å. If the thickness of the encapsulation layer 130 is less than 3000 Å, a gap between the color filter structure CFS and the spacer 140 may be too small, so that the wet etch process may not be smoothly performed, and thus the encapsulation layer 130 may not be disconnected. And, when the thickness of the encapsulation layer 130 exceeds 8000 Å, the thickness of the encapsulation layer 130 is too thick, so that the tact time of the wet etch process increases, which may reduce the yield. Therefore, the transparent display apparatus 100 according to FIG. 6 is provided with the thickness of the encapsulation layer 130 of 3000 Å to 8000 Å, so that the encapsulation layer 130 can be easily separated into the first encapsulation layer 131 and the second encapsulation layer 132, and the yield can be increased by reducing the tact time.

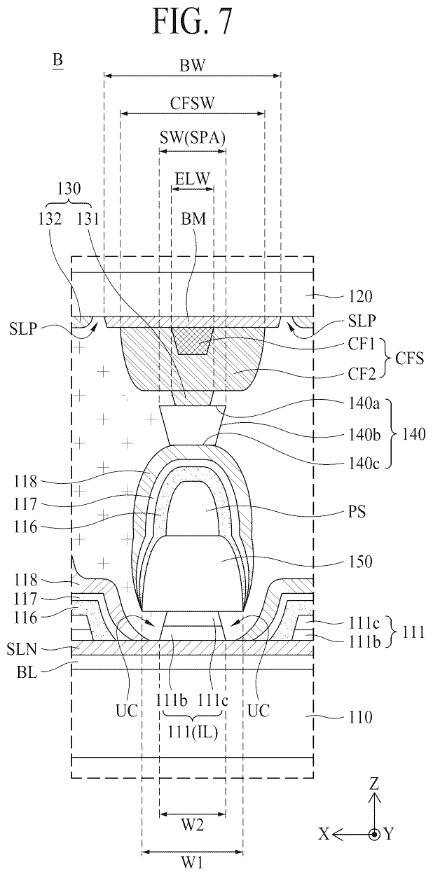

FIG. 7 is a schematic cross-sectional view showing a fourth example of portion B in FIG. 3 according to one embodiment.

In the case of the transparent display apparatus 100 according to FIG. 7, it is the same as the transparent display apparatus 100 according to FIG. 6 described above, except that the space portion S is omitted and a slit portion SLP is added due to a change in the structure of the encapsulation layer 130. Therefore, the same drawing symbols have been assigned to the same configuration, and only the different configurations will be described hereinafter.

In the case of the transparent display apparatus according to the aforementioned FIG. 6, the portion of the encapsulation layer 130 between the spacer 140 and the color filter structure CFS is removed through a wet etching process, so that the space portion S can be provided between the first encapsulation layer 131 and the second encapsulation layer 132. Accordingly, in the transparent display apparatus according to FIG. 6, the second encapsulation layer 132 can partially cover the black matrix BM and the color filter structure CFS, and even if an external impact occurs, cracks may not propagate to the light emission area EA through the second encapsulation layer 132, so that moisture penetration into the light-emitting element can be prevented, thereby improving reliability.

In contrast, in the case of the transparent display apparatus according to FIG. 7, the second encapsulation layer 132 may be provided so as not to overlap with the black matrix BM (or the black matrix BM in the transmissive area TA). This is because, in the process of removing the encapsulation layer 130 covering the color filter structure CFS, an area from which the encapsulation layer 130 is removed is set to be larger than in the transparent display apparatus according to FIG. 6. Or, in the process of removing the encapsulation layer 130 covering the color filter structure CFS, the etching time for removing the encapsulation layer 130 is set longer than that of the transparent display apparatus according to FIG. 6. Accordingly, in the case of the transparent display apparatus according to FIG. 7, the second encapsulation layer 132 may not overlap with the black matrix BM but may be disconnected with the black matrix BM interposed therebetween. In addition, in the case of the transparent display apparatus according to FIG. 7, since a removal area of the encapsulation layer 130 is wider than that of the transparent display apparatus according to FIG. 6, the color filter structure CFS may have a structural feature in which it is not covered by the second encapsulation layer 132.

Meanwhile, the transparent display apparatus 100 according to FIG. 7 may further include the slit portion SLP provided between the second encapsulation layer 132 and the black matrix BM. As described above, in the case of the transparent display apparatus according to FIG. 7, since the removal area of the encapsulation layer 130 is wider than that of the transparent display apparatus according to FIG. 6, the second encapsulation layer 132 may be formed spaced apart from the black matrix BM in the transmissive area TA. Accordingly, the slit portion SLP may be formed between the black matrix BM and the second encapsulation layer 132. Since the transparent display apparatus 100 according to FIG. 7 has the slit portion SLP between the second encapsulation layer 132 and the black matrix BM functioning as a support, even if an external impact occurs, a crack may not propagate to the light emission area EA through the second encapsulation layer 132, so that moisture penetration into the light-emitting element may be prevented or at least reduced, thereby improving reliability.

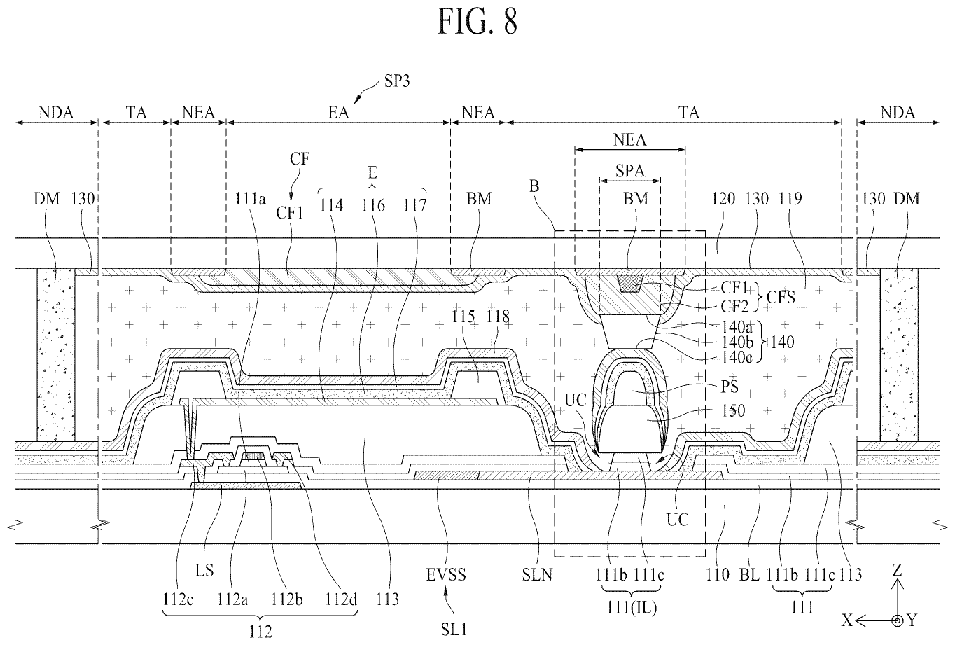

FIG. 8 is a schematic cross-sectional view showing a dam of a transparent display apparatus according to one embodiment of the present disclosure.

Referring to FIG. 1, the transparent display apparatus 100 according to one embodiment of the present disclosure may further include a dam DM arranged in the non-display area NDA surrounding the display area DA.

According to one example, the dam DM is provided to prevent or at least reduce moisture and oxygen from penetrating into the display area DA. Therefore, the dam DM is provided in a closed form, for example, in a closed loop form, while being placed at each edge of the substrate 110 and the opposing substrate 120. As shown in FIG. 1, the dam DM according to one example can be placed in the non-display area NDA surrounding the display area DA and the gate driver GD.

Referring to FIG. 8, in the transparent display apparatus 100 according to one embodiment of the present disclosure, the encapsulation layer 130 may be positioned inside the dam DM and may be provided so as not to overlap with the dam DM. When the encapsulation layer 130 is placed so as to overlap the dam DM, a crack may occur in the encapsulation layer 130 due to an external impact generated at the edge of the substrate 110 and/or the opposing substrate 120, and this crack may propagate to the light emission area EA through the encapsulation layer 130 overlapped with the dam DM, causing moisture penetration into the light-emitting element. Accordingly, the transparent display apparatus 100 according to one embodiment of the present disclosure is provided such that the encapsulation layer 130 is positioned inside the dam DM and does not overlap with the dam DM, thereby preventing cracks from occurring in the encapsulation layer 130 due to external impact occurring at the edge of the substrate 110 and/or the opposing substrate 120.

Meanwhile, in the transparent display apparatus 100 according to one embodiment of the present disclosure, the encapsulation layer 130 (or inorganic encapsulation layer 130) can be formed through a low-temperature process. For example, the temperature of the low-temperature process in which the encapsulation layer 130 (or inorganic encapsulation layer 130) is formed may be about 230 degrees. This is because, if the encapsulation layer 130 (or inorganic encapsulation layer 130) is formed in a high temperature process (e.g., a temperature of 430 degrees), the color filter CF already formed on the opposing substrate 120 before the formation of the encapsulation layer 130 may be damaged by the high temperature. Therefore, in the transparent display apparatus 100 according to one embodiment of the present disclosure, since the encapsulation layer 130 (or inorganic encapsulation layer 130) is formed in a low temperature process of about 230 degrees or less, damage to the color filter CF can be prevented.

In addition, in the transparent display apparatus 100 according to one embodiment of the present disclosure, the encapsulation layer 130 (or inorganic encapsulation layer 130) can be formed under process conditions in which a composition ratio of SiH₄:N₂O is 1:30 to 1:40. If the composition ratio of SiH₄:N₂O exceeds 1:30, the encapsulation layer 130 (or inorganic encapsulation layer 130) may be lifted off from the opposing substrate 120. And, when the composition ratio of SiH₄:N₂O is less than 1:40, the opposing substrate 120 on which the encapsulation layer 130 (or inorganic encapsulation layer 130) is formed can be bent. Therefore, the transparent display apparatus 100 according to one embodiment of the present disclosure can be provided such that the encapsulation layer 130 (or inorganic encapsulation layer 130) is formed on the opposing substrate 120 under process conditions in which the composition ratio of SiH₄:N₂O is 1:30 to 1:40, so that the opposing substrate 120 is not bent without the encapsulation layer 130 (or inorganic encapsulation layer 130) being lifted off from the opposing substrate 120. That is, in the transparent display apparatus 100 according to one embodiment of the present disclosure, the encapsulation layer 130 (or inorganic encapsulation layer 130) is formed on the opposing substrate 120 under process conditions in which the composition ratio of SiH₄:N₂O is 1:30 to 1:40, so that a stress of the encapsulation layer 130 (or inorganic encapsulation layer 130) is improved and the defect rate can be reduced.

Meanwhile, in the transparent display apparatus 100 according to one embodiment of the present disclosure, an N₂ pretreatment process is performed on the color filter structure CFS before the encapsulation layer 130 (or the inorganic encapsulation layer 130) is formed under process conditions where the composition ratio of SiH₄:N₂O is 1:30 to 1:40, so that an adhesion of the encapsulation layer 130 (or inorganic encapsulation layer 130) to the color filter structure CFS can be increased, and thus the robustness and/or reliability against external impact can be improved.

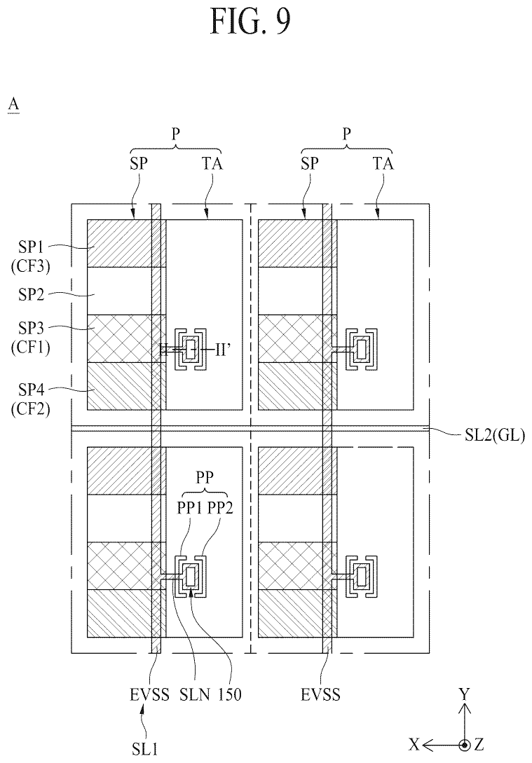

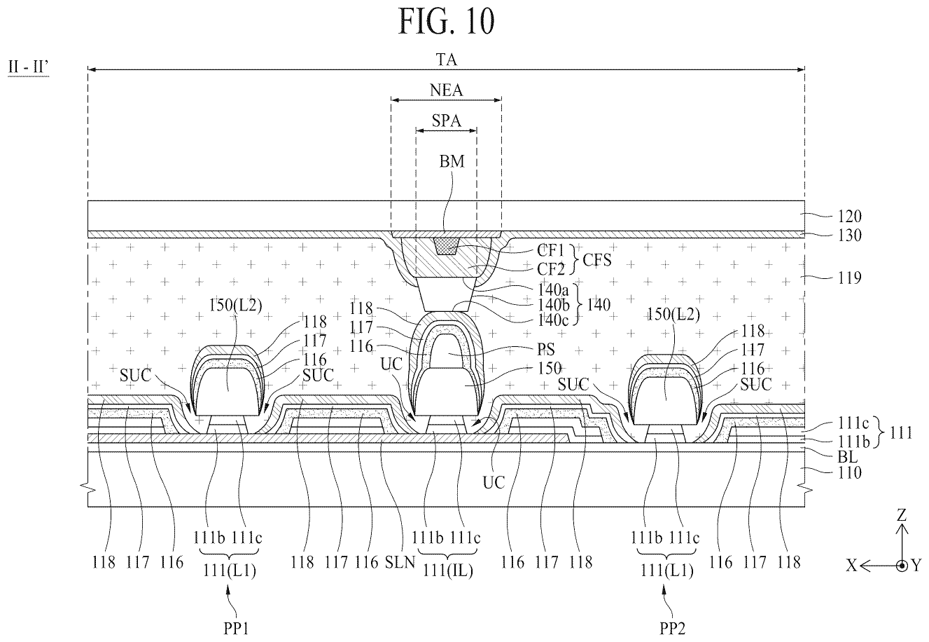

FIG. 9 is a schematic plan view showing another example of portion A of FIG. 1, relating to a transparent display apparatus according to another embodiment of the present disclosure, and FIG. 10 is a schematic cross-sectional view of the line II-II′ shown in FIG. 9 according to one embodiment.

Referring to FIGS. 9 and 10, the transparent display apparatus 100 according to another embodiment of the present disclosure is the same as the transparent display apparatus according to FIG. 1 described above, except that a plurality of partition walls PP are added. Therefore, the same drawing symbols have been assigned to the same configuration, and only the different configurations will be described hereinafter.

In the case of the transparent display apparatus according to FIG. 1, the lower encapsulation layer 118 can be disconnected by an undercut portion UC adjacent to the inorganic film layer IL over the auxiliary line SLN. Accordingly, in the case of the transparent display apparatus according to FIG. 1, since the lower encapsulation layer 118 can be primarily cut off by the undercut portion UC, cracks caused by external impact do not propagate to the lower encapsulation layer 118 covering the light emitting element layer E of each of the plurality of subpixels SP, thus preventing moisture penetration into the light emitting element (or light emitting element layer E), and thus improving reliability.

In contrast, in the case of the transparent display apparatus according to FIG. 9, a plurality of partition walls PP arranged spaced apart from the planarization layer 150 on the substrate 110 may be further included. The plurality of partition walls PP are intended to secondarily prevent cracks in the lower encapsulation layer 118 between the pattern structure PS and the spacer 140 from spreading to the surroundings when a crack occurs in the lower encapsulation layer 118 between the pattern structure PS and the spacer 140 due to external impact. Accordingly, the plurality of partition walls PP may be arranged at least in a portion of the periphery of the planarization layer 150 arranged on the auxiliary line SLN, and each of the plurality of partition walls PP may include an auxiliary undercut portion SUC that disconnects the lower encapsulation layer 118. According to one example, the auxiliary undercut portion SUC may be formed by partially removing the interlayer insulating layer 111b and the passivation layer 111c.

Meanwhile, as shown in FIG. 10, in the transparent display apparatus 100 according to another embodiment of the present disclosure, each of the plurality of partition walls PP may include a first layer L1 and a second layer L2. The first layer L1 may be formed of the same material as the inorganic film layer IL. The first layer L1 may be composed of the interlayer insulating layer 111b and the passivation layer 111c disposed on the interlayer insulating layer 111b. According to one example, the first layer L1 may be provided in an island shape because it is surrounded by the auxiliary undercut portion SUC. The second layer L2 is disposed on the first layer L1 and may be formed of the same material as the planarization layer 150. The second layer L2 may be formed in a tapered shape to serve as an eaves when forming the auxiliary undercut portion SUC. Since the organic light-emitting layer 116, the opposing electrode 117, and the lower encapsulation layer 118 are sequentially deposited on the entire surface after the plurality of partition walls PP are formed, the organic light-emitting layer 116, the opposing electrode 117, and the lower encapsulation layer 118 can be provided discontinuously by being disconnected by the auxiliary undercut portion SUC. Accordingly, as shown in FIG. 10, the organic light-emitting layer 116 disconnected by the auxiliary undercut portion SUC, the opposing electrode 117 disconnected by the auxiliary undercut portion SUC, and the lower encapsulation layer 118 disconnected by the auxiliary undercut portion SUC can be arranged on the second layer L2.

As a result, the transparent display apparatus 100 according to another embodiment of the present disclosure is provided to include the plurality of partition walls PP spaced apart from the planarization layer 150, so that even if a crack occurs in the lower encapsulation layer 118 on the planarization layer 150 due to an external impact, the crack cannot primarily propagate toward the light emission area EA due to the lower encapsulation layer 118 being disconnected by the undercut portion UC, and additionally, the crack cannot secondarily propagate toward the light emission area EA due to the lower encapsulation layer 118 being disconnected by the auxiliary undercut portion SUC. Accordingly, in the transparent display apparatus 100 according to another embodiment of the present disclosure, cracks in the lower encapsulation layer 118 caused by external impact are doubly blocked through the undercut portion UC of the planarization layer 150 and the auxiliary undercut portion SUC of the plurality of partition walls PP, thereby maximizing the blocking of crack propagation through the lower encapsulation layer 118, and thus further preventing moisture penetration into the light-emitting element.

Meanwhile, the plurality of partition walls PP according to one example may include a first partition wall PP1 and a second partition wall PP2. Each of the first partition wall PP1 and the second partition wall PP2 is provided with a first layer L1 and a second layer L2, and the auxiliary undercut portion SUC may be formed on a lower portion of the second layer L2. As shown in FIG. 9, the first partition wall PP1 may overlap at least partly with the auxiliary line SLN. In contrast, the second partition wall PP2 may be spaced apart from the first partition wall PP1 with the planarization layer 150 interposed therebetween and may not overlap with the auxiliary line SLN.

According to one example, the first partition wall PP1 may be formed symmetrically with the second partition wall PP2 with the planarization layer 150 interposed therebetween, as shown in FIG. 9. For example, each of the first partition wall PP1 and the second partition wall PP2 is configured in a “C” shape, and the first partition wall PP1 may be arranged on the subpixel SP and the planarization layer 150, and the second partition wall PP2 may be arranged in the transmissive area TA that does not overlap with the auxiliary line SLN. Accordingly, the transparent display apparatus 100 according to another embodiment of the present disclosure is provided with the plurality of partition walls PP (or the first partition wall PP1 and the second partition wall PP2) arranged around the planarization layer 150, so that even if a crack occurs in the lower encapsulation layer 118 on the planarization layer 150 due to an external impact, the crack propagation is doubly blocked by the undercut portion UC and the auxiliary undercut portion SUC, so that the reliability of the light-emitting element can be further improved.

Embodiments of the present disclosure have been described in more detail with reference to the accompanying drawings, but the present disclosure is not necessarily limited to these embodiments and may be implemented in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this disclosure shall be construed by the claims, and all technical ideas within the scope of the claims shall be construed to be included within the scope of the claims.

The present disclosure provides a spacer between a substrate and an opposing substrate, so that a cell gap between the substrate (a lower substrate) and the opposing substrate (an upper substrate) can be maintained.

Furthermore, the present disclosure is provided such that an encapsulation layer is cut off, thereby blocking crack propagation through an encapsulation layer.

Furthermore, the present disclosure is provided so that crack propagation is blocked, thereby preventing moisture penetration into a light-emitting element.

Furthermore, the present disclosure is provided to block crack propagation due to a disconnection of the encapsulation layer, thereby improving the life of the light-emitting element, and thus enabling the light-emitting element to be driven at lower power compared to its entire lifespan, thereby reducing power consumption.

Furthermore, in the present disclosure, since the encapsulation layer is formed of an inorganic layer, the thickness of the encapsulation layer can be reduced compared to when the encapsulation layer is formed of an organic layer, thereby increasing the cell gap.

Furthermore, the present disclosure can improve the viewing angle due to the thin thickness of the encapsulation layer.

Furthermore, the present disclosure can prevent dark spot defects caused by external force by increasing the cell gap.

The effects that may be obtained from the present disclosure are not limited to those mentioned above, and other effects not mentioned will be apparent to one having ordinary skill in the art from the following description.

What is claimed is:

1. A transparent display apparatus comprising:
a substrate including a plurality of pixels, each of the plurality of pixels comprising a transmissive area and a plurality of subpixels;
an opposing substrate on the substrate;
an encapsulation layer that partially covers the opposing substrate; and
a spacer between the opposing substrate and the substrate, the spacer overlapping the transmissive area,
wherein the opposing substrate includes a support area overlapping the spacer and the encapsulation layer is disconnected in at least a portion of the support area.

2. The transparent display apparatus of claim 1, wherein the encapsulation layer includes an inorganic material.

3. The transparent display apparatus of claim 1, further comprising:
a black matrix on the opposing substrate and overlapping the support area; and
a color filter structure on the black matrix.

4. The transparent display apparatus of claim 3, wherein a width of the color filter structure is greater than a width of the spacer and smaller than a width of the black matrix.

5. The transparent display apparatus of claim 3, wherein an upper surface of the spacer is in contact with the color filter structure and the encapsulation layer is in contact with a side surface of the spacer while covering the black matrix and the color filter structure.

6. The transparent display apparatus of claim 3, wherein the encapsulation layer is separated by the black matrix.

7. The transparent display apparatus of claim 6, wherein the color filter structure is not covered by the encapsulation layer.

8. The transparent display apparatus of claim 6, further comprising:
a slit portion between the encapsulation layer and the black matrix.

9. The transparent display apparatus of claim 3, wherein the encapsulation layer comprises:
a first encapsulation layer between the color filter structure and the spacer; and
a second encapsulation layer that is spaced apart from the first encapsulation layer.

10. The transparent display apparatus of claim 9, wherein the second encapsulation layer partially covers the black matrix and the color filter structure.

11. The transparent display apparatus of claim 9, wherein a width of the first encapsulation layer is smaller than a width of the spacer.

12. The transparent display apparatus of claim 9, further comprising:
a space portion between the first encapsulation layer and the second encapsulation layer.

13. The transparent display apparatus of claim 9, wherein the second encapsulation layer is non-overlapping with the black matrix.

14. The transparent display apparatus of claim 13, further comprising:
a slit portion between the second encapsulation layer and the black matrix.

15. The transparent display apparatus of claim 1, further comprising:
an auxiliary line on the substrate;
a planarization layer on the auxiliary line;
an inorganic film layer between the planarization layer and the auxiliary line, the inorganic film layer having a width that is narrower than a width of the planarization layer; and
an undercut portion adjacent to the inorganic film layer.

16. The transparent display apparatus of claim 15, wherein each of the plurality of subpixels includes a plurality of light-emitting element layers that emit light,
wherein the substrate includes a lower encapsulation layer covering the plurality of light-emitting element layers and the lower encapsulation layer is disconnected by the undercut portion.

17. The transparent display apparatus of claim 16, wherein each of the plurality of subpixels comprises:
an overcoat layer on the substrate;
a pixel electrode on the overcoat layer;
an organic light-emitting layer on the pixel electrode; and
an opposing electrode on the organic light-emitting layer, the opposing electrode in contact with the auxiliary line at the undercut portion.

18. The transparent display apparatus of claim 17, further comprising:
a pattern structure on an upper surface of the planarization layer,
wherein the pattern structure is covered by the organic light-emitting layer, the opposing electrode, and the lower encapsulation layer, and
wherein each of the organic light-emitting layer covering the pattern structure, the opposing electrode covering the pattern structure, and the lower encapsulation layer covering the pattern structure is disconnected by the undercut portion and is discontinuous.

19. The transparent display apparatus of claim 18, wherein the lower encapsulation layer covering the pattern structure is in contact with a lower surface of the spacer.

20. The transparent display apparatus of claim 1, further comprising:
a dam on each edge of the substrate and the opposing substrate,
wherein the encapsulation layer is disposed inside the dam and is non-overlapping with the dam.

21. The transparent display apparatus of claim 16, further comprising:
a plurality of partition walls arranged spaced apart from the planarization layer on the substrate,
wherein each of the plurality of partition walls includes an auxiliary undercut portion that disconnects the lower encapsulation layer.

22. The transparent display apparatus of claim 21, wherein each of the plurality of partition walls comprises:
a first layer including a same material as the inorganic film layer; and
a second layer on the first layer and including a same material as the planarization layer.

23. The transparent display apparatus of claim 21, wherein the plurality of partition walls include:
a first partition wall overlapping at least a portion of the auxiliary line; and
a second partition wall spaced apart from the first partition wall and non-overlapping with the auxiliary line.

24. The transparent display apparatus of claim 23, wherein the first partition wall is symmetrical with the second partition wall with the planarization layer between the first partition wall and the second partition wall.

25. The transparent display apparatus of claim 1, wherein the encapsulation layer is formed through a low-temperature process.

26. The transparent display apparatus of claim 1, wherein the encapsulation layer is formed under process conditions in which a composition ratio of SiH₄:N₂O is 1:30 to 1:40.

27. The transparent display apparatus of claim 1, wherein a thickness of the encapsulation layer is in a range from 3000 Å to 8000 Å.

28. The transparent display apparatus of claim 15, wherein the planarization layer is arranged in the transmissive area.
